(19) United States
(12) Patent Application Publication
(10) Pub. No.: US 2015/0135517 A1
(43) Pub. Date: May 21, 2015

(54) DEGRADATION DIAGNOSIS DEVICE FOR CELL, DEGRADATION DIAGNOSIS METHOD, AND METHOD FOR MANUFACTURING CELL

(71) Applicants: Takayoshi Doi, Toyota-shi (JP); Masahiro Nakayama, Susono-shi (JP); Satoshi Yoshida, Susono-shi (JP); Yuzo Miura, Susono-shi (JP)

(72) Inventors: Takayoshi Doi, Toyota-shi (JP); Masahiro Nakayama, Susono-shi (JP); Satoshi Yoshida, Susono-shi (JP); Yuzo Miura, Susono-shi (JP)

(73) Assignee: TOYOTA JIDOSHA KABUSHIKI KAISHA, Toyota-shi, Aichi (JP)

(21) Appl. No.: 14/399,412

(22) PCT Filed: Jun. 1, 2012
(86) PCT No.: PCT/JP2012/064281

§ 371 Date: Nov. 6, 2014

(51) Int. Cl. G01R 31/36; H01M 10/42; H01M 10/04; H01M 10/44

(52) U.S. Cl. CPC G01R 31/3634; H01M 10/44; H01M 10/4285; H01M 10/04
USPC 29/593; 324/427

(57) ABSTRACT

The present invention provides a degradation diagnosis device for a cell, the degradation diagnosis device for a cell comparing a potential variation characteristic of a comparison subject cell during discharging and after discharging is stopped and a potential variation characteristic of a degradation diagnosis subject cell during discharging and after discharging is stopped, in a case where the potential variation characteristic of the comparison subject cell during discharging and after discharging is stopped and the potential variation characteristic of the degradation diagnosis subject cell during discharging and after discharging is stopped are not same, diagnosing a cause of the degradation as including degradation of an active material, and in a case where they are same, diagnosing the cause of the degradation as being other than the active material.

### BACKGROUND OF THE INVENTION

1. Field of the Invention

The present invention relates to a degradation diagnosis device for a cell, a degradation diagnosis method, and a method for manufacturing a cell employing the degradation diagnosis method.

2. Description of the Related Art

A lithium-ion secondary battery has a higher energy density and is operable at a high voltage compared to other secondary batteries. Therefore, it is used for information devices such as a cellular phone, as a secondary battery which can be easily reduced in size and weight, and nowadays there is also an increasing demand for the lithium-ion secondary battery to be used as a power source for large-scale apparatuses such as electric vehicles and hybrid vehicles.

A lithium-ion secondary battery includes a cathode layer, an anode layer, and an electrolyte layer disposed between them. An electrolyte to be employed in the electrolyte layer is, for example, a non-aqueous liquid or a solid. When the liquid is used as the electrolyte (hereinafter, the liquid being referred to as “electrolytic solution”), it easily permeates into the cathode layer and the anode layer. Therefore, an interface can be formed easily between the electrolytic solution and active materials contained in the cathode layer and the anode layer, and the battery performance can be easily improved. However, since commonly used electrolytic solutions are flammable, it is necessary to mount a system to ensure safety. On the other hand, if a nonflammable solid electrolyte (hereinafter referred to as “solid electrolyte”) is used, the above system can be simplified. As such, a lithium-ion secondary battery provided with a layer containing a solid electrolyte has been suggested (hereinafter, the layer being referred to as “solid electrolyte layer” and the battery being referred to as “all-solid battery”).

As a technique related to the lithium-ion secondary battery, for example Patent Document 1 discloses a technique related to a vehicle control device which stops an engine by stopping idle operation when idol stop conditions are satisfied and starts the engine by cranking with a polyphase AC motor when engine start conditions are satisfied.

### CITATION LIST

### Patent Literatures

Patent Document 1: Japanese Patent Application Laid-Open Publication No. 2011-52594

### SUMMARY OF THE INVENTION

### Problem to be Solved by Invention

With the technique disclosed in Patent Document 1, after the polyphase AC motor starts rotating, a degradation degree of a battery is estimated based on battery characteristics when a rotor is at a predetermined attitude. However, with this technique, although the degree of degradation of a cell can be estimated, the causes of degradation cannot be specified.

Accordingly, an object of the present invention is to provide a degradation diagnosis device for a cell and a degradation diagnosis method that are capable of specifying the cause of degradation, and a method for manufacturing a cell employing the degradation diagnosis method.

### Means for Solving the Problems

As a result of an intensive study, the inventors of the present invention have found the following: a cell in which an active material is not degraded is easy to recover its potential immediately after discharging is stopped (has a large degree of potential recovery immediately after discharging is stopped); however, a cell in which an active material is degraded has a moderate degree of potential recovery immediately after discharging is stopped, compared to the cell in which the active materials is not degraded (requires a long time until the potential is saturated after discharging is stopped). Therefore, it can be considered that it becomes possible to diagnose whether a cell is difficult to recover its cell performance only by replacing the electrolyte and the like since the active material of the cell is degraded, or the cell is easy to recover the cell performance only by replacing the electrolyte and the like since a substance other than the active material is degraded. The present invention has been made based on the above findings.

In order to solve the above problems, the present invention takes the following means. Namely, a first aspect of the present invention is a degradation diagnosis device for a cell, the device including: a memory unit for storing a potential variation characteristic of a comparison subject cell during discharging and after discharging is stopped; and a specifying unit for comparing a potential variation characteristic of a degradation diagnosis subject cell during discharging and after discharging is stopped and the potential variation characteristic of the comparison subject cell during discharging and after discharging is stopped stored in the memory unit to specify a cause of degradation of the degradation diagnosis subject cell, based on a difference between the potential variation characteristic of the degradation diagnosis subject cell during discharging and after discharging is stopped and the potential variation characteristic of the comparison subject cell during discharging and after discharging is stopped, wherein in the specifying unit, in a case where a potential of the degradation diagnosis subject cell immediately after discharging is stopped is not same as a potential of the comparison subject cell immediately after discharging is stopped, the cause of degradation is diagnosed as including degradation of an active material, and in a case where the potential of the degradation diagnosis subject cell immediately after discharging is stopped is same as the potential of the comparison subject cell immediately after discharging is stopped, the cause of degradation is diagnosed as being other than the active material.

Here, in the first aspect of the present invention and other aspects of the present invention described later (hereinafter the first and other aspects are sometimes collectively referred to as “the present invention”), the “comparison subject cell” means, for example, a cell capable of exhibiting the initial performance expected when manufactured. In the present invention, “immediately after discharging is stopped” means for example in 1 second after discharging is stopped, preferably in 0.1 second after discharging is stopped. Also, in the present invention, “the potential of the degradation diagnosis subject cell immediately after discharging is stopped is same as the potential of the comparison subject cell immediately after discharging is stopped” means not only a situation where the potential of the degradation diagnosis cell immediately after discharging is stopped and the potential of the comparison subject cell immediately after discharging is stopped (hereinafter sometimes referred to as “both potentials”) are completely identical, but also a situation where the difference of the both potentials is of a predetermined value or less. The determination method of the “predetermined value” is not particularly limited, and for example, in a case where the difference of the both potentials is several % or less (for example, 1% or less) of the potential of the comparison subject cell immediately after discharging is stopped, the comparison subject cell being capable of exhibiting the initial performance expected when manufactured, the predetermined value may be determined so that the cause of degradation is diagnosed as being other than the active material. In the present invention, discharging time in the degradation diagnosis is not particularly limited, and may be adequately adjusted depending on discharging rate. Ina case where the discharging is carried out in the degradation diagnosis at a high rate (for example a discharging rate of 3 C or more and the like. The same is applied hereinafter), the discharging may be carried out for example for approximately 0.1 second or more and 60 seconds or less. In a case where the discharging is carried out at a low rate (for example, a discharging rate of less than 3 C and the like) as well, the discharging may be carried out for example for approximately 0.1 second or more and 60 seconds or less.

Potential variation during discharging includes variation caused by transfer of electrons and ions, and variation caused by the equilibrium potential variation of active material. Therefore, it is difficult to specify the variation caused by the equilibrium potential variation of active material only by comparing the potential variation during discharging. However, after discharging is stopped, since only the variation caused by the equilibrium potential variation of active material is remained, it is possible to easily specify the potential variation caused by the equilibrium potential variation of active material. Regarding a cell having a small equilibrium potential variation of active material after a predetermined time longer than the time included in the above “immediately after discharging is stopped” (hereinafter simply referred to as “predetermined time”) is passed after discharging is stopped (that is, for example, in a case where the potential of the degradation diagnosis subject cell immediately after discharging is stopped is same as the potential of the comparison subject cell immediately after discharging is stopped, the comparison subject cell being capable of exhibiting the initial performance expected when manufactured), it can be considered that the cell has a configuration in which the active material is easy to storage/release ions and ions are easy to transfer. Therefore, it is possible to diagnose that the active material is not degraded. In contrast, regarding a cell having a large equilibrium potential variation of active material after the predetermined time is passed after the discharging is stopped (that is, for example, in a case where the potential of the degradation diagnosis subject cell immediately after discharging is stopped is not same as the potential of the comparison subject cell immediately after discharging is stopped, the comparison subject cell being capable of exhibiting the initial performance expected when manufactured), it can be considered that the cell has a configuration in which the active material is difficult to storage/release ions. Therefore, it is possible to diagnose that the active material is degraded. Therefore, according to the first aspect of the present invention carrying out the degradation diagnosis for a cell as described above, it is possible to provide a degradation diagnosis device for a cell capable of specifying the cause of degradation of a cell.

A second aspect of the present invention is a degradation diagnosis device for a cell, the device including a specifying unit for specifying a cause of degradation of a degradation diagnosis subject cell by means of at least a potential variation characteristic of the degradation diagnosis subject cell after discharging is stopped, wherein in the specifying unit, in a case where a potential of the degradation diagnosis subject cell immediately after discharging is stopped is smaller than a predetermined potential, a cause of degradation is diagnosed as including degradation of an active material, and in a case where the potential of the degradation diagnosis subject cell immediately after discharging is stopped is same as or larger than the predetermined potential, the cause of degradation is diagnosed as being other than the active material.

Here, in the second aspect of the present invention and the other aspects of the present invention described below, “predetermined potential” means, for example, a potential of a cell immediately after discharging is stopped, the cell being capable of exhibiting the initial performance expected when manufactured. As described above, whether the degradation of the active material is included in the cause of degradation or not may be judged by whether the potential immediately after discharging is stopped is less than the predetermined potential or not. Here, in the second aspect of the present invention, whether the potential immediately after discharging is stopped is less than the predetermined potential or not is examined. Therefore, according to the second aspect of the present invention, it is possible to provide a degradation diagnosis device for a cell capable of specifying whether the cause of degradation of a cell includes degradation of an active material or not, that is, capable of specifying the cause of degradation of the cell.

Also, in the first aspect and the second aspect of the present invention, during the degradation diagnosis subject cell is discharged, in a case where the potential does not drop to a minimum potential which is acceptable based on a use form of the degradation diagnosis subject cell, the degradation diagnosis subject cell can be diagnosed as capable of being continuously used. The cell satisfying performance criteria depending on the use form can be continuously used without any performance recovery measure. Therefore, the above configuration makes it possible to provide a degradation diagnosis device for a cell capable of diagnosing whether a cell can be continuously used or not in addition to diagnosing the cause of degradation of the cell.

A third aspect of the present invention is a degradation diagnosis method for a cell, the method including: a pre-degradation characteristic grasping step of grasping a potential variation characteristic of a comparison subject cell during discharging and after discharging is stopped; a characteristic obtaining step of obtaining a potential variation characteristic of a degradation diagnosis subject cell during discharging and after discharging is stopped; and a degradation cause specifying step of comparing the potential variation characteristic of the comparison subject cell obtained in the pre-degradation characteristic grasping step and the potential variation characteristic of the degradation diagnosis subject cell obtained in the characteristic obtaining step to specify a cause of degradation of the degradation diagnosis subject cell based on a difference between the potential variation characteristic obtained in the pre-degradation characteristic grasping step and the potential variation characteristic obtained in the characteristic obtaining step, wherein the degradation cause specifying step includes: in a case where a potential of the degradation diagnosis subject cell immediately after discharging is stopped which is obtained in the characteristic obtaining step is not same as a potential of the comparison subject cell immediately after discharging is stopped which is obtained in the pre-degradation characteristic grasping step, diagnosing the cause of degradation as including degradation of an active material; and in a case where the potential of the degradation diagnosis subject cell immediately after discharging is stopped which is obtained in the characteristic obtaining step is same as the potential of the comparison subject cell immediately after discharging is stopped which is obtained in the pre-degradation characteristic grasping step, diagnosing the cause of degradation as being other than the active material.

As described above, regarding the cell having a small equilibrium potential variation of active material after the predetermined time is passed after discharging is stopped, it can be considered that the cell has a configuration in which the active material is easy to storage/release ions and the ions can easily transfer. Therefore, it is possible to diagnose that the active material is not degraded. In contrast, regarding the cell having a large equilibrium potential variation of active material after the predetermined time is passed after discharging is stopped, it can be considered that the cell has a configuration in which the active material is difficult to storage/release ions. Therefore, it is possible to diagnose that the active material is degraded. Therefore, according to the third aspect of the present invention having the degradation cause specifying step in which the degradation diagnosis for a cell is carried out as described above, it is possible to provide a degradation diagnosis method for a cell capable of specifying the cause of degradation of a cell.

A fourth aspect of the present invention is a degradation diagnosis method for a cell, the method including: a characteristic obtaining step of obtaining at least a potential variation characteristic of a degradation diagnosis subject cell after discharging is stopped; and a degradation cause specifying step of specifying a cause of degradation of the degradation diagnosis subject cell by means of the potential variation characteristic obtained in the characteristic obtaining step, wherein the degradation cause specifying step includes; in a case where a potential of the degradation diagnosis subject cell immediately after discharging is stopped is smaller than a predetermined potential, diagnosing the cause of degradation as including degradation of an active material; and in a case where the potential of the degradation diagnosis subject cell immediately after discharging is stopped is same as or larger than the predetermined potential, diagnosing the cause of degradation as being other than the active material.

As described above, by examining the potential characteristic after discharging is stopped, it is possible to judge whether the cause of degradation includes degradation of the active material or not. The fourth aspect of the present invention includes the degradation cause specifying step of examining whether the potential immediately after discharging is less than the predetermined potential or not. Therefore, according to the fourth aspect of the present invention, it is possible to provide a degradation diagnosis method for a cell capable of specifying whether the cause of degradation of a cell includes degradation of an active material or not, that is, capable of specifying the cause of degradation of the cell.

In the third aspect and the fourth aspect of the present invention, during the degradation diagnosis subject cell is discharged, in a case where the potential does not drop to a minimum potential which is acceptable based on a use form of the degradation diagnosis subject cell, the degradation diagnosis subject cell is diagnosed as capable of being continuously used. The cell satisfying performance criteria depending on the use form can be continuously used without any performance recovery measure. Therefore, the above configuration makes it possible to provide a degradation diagnosis method for a cell capable of diagnosing whether a cell can be continuously used or not in addition to diagnosing the cause of degradation of the cell.

A fifth aspect of the present invention is a method for manufacturing a cell, the method including: a cell producing step; a degradation diagnosis step of carrying out a degradation diagnosis to a cell produced in the cell producing step, by means of the degradation diagnosis method for a cell according to the third aspect or the fourth aspect of the present invention; and a diagnosis result reflection step including: if the cell is diagnosed in the degradation diagnosis step that a cause of degradation includes degradation of an active material, replacing the cell by a single cell unit; and if the cell is diagnosed in the degradation diagnosis step that the cause of degradation is other than the active material, replacing an electrolyte of the cell or pressing the cell.

In a manufacturing step of a cell, by including the degradation diagnosis step of carrying out the degradation diagnosis to a cell by means of the degradation diagnosis method for a cell according to the third aspect or the fourth aspect of the present invention and the diagnosis result reflection step of reflecting the diagnosis result in the degradation diagnosis step, it is possible to specify a cell which does not satisfy the performance criteria to be satisfied by a product in advance before the product is shipped out, thereby shipping out the specified cell after recovering the performance, and to ship out only cells that satisfy the performance criteria. According to this configuration, it is possible to improve the quality of the product (cell) to be shipped out. Therefore, according to the fifth aspect of the present invention, it is possible to provide a method for manufacturing a cell by which the quality of a cell can be improved.

### Effects of the Invention

According to the present invention, it is possible to provide a degradation diagnosis device for a cell and a degradation diagnosis method for a cell that are capable of specifying the cause of degradation of a cell, and a method for manufacturing a cell employing the degradation diagnosis method.

### BRIEF DESCRIPTION OF THE DRAWINGS

FIG. 1 is a graph to explain a potential variation characteristic of a comparison subject cell during discharging and after discharging is stopped;

FIG. 2 is a graph to explain a potential variation characteristic of a degraded cell during discharging and after discharging is stopped;

FIG. 3 is a graph to explain a potential variation characteristic of a degraded cell during discharging and after discharging is stopped;

FIG. 4 is a graph showing results of potential variation characteristics during discharging and after discharging is stopped;

FIG. 5 is a graph showing differences between the potential when discharging is started and the potential immediately after discharging is stopped;

FIG. 6 is a photograph showing observations by means of a transmission electron microscope;

FIG. 7 is a graph showing resistances at an early stage of examination, after 100 cycles are carried out, and after performance recovering treatment is carried out.

### DETAILED DESCRIPTION OF THE INVENTION

Hereinafter, the present invention will be described with reference to the drawings. It should be noted that the embodiments shown below are examples of the present invention and the present invention is not limited to these embodiments.

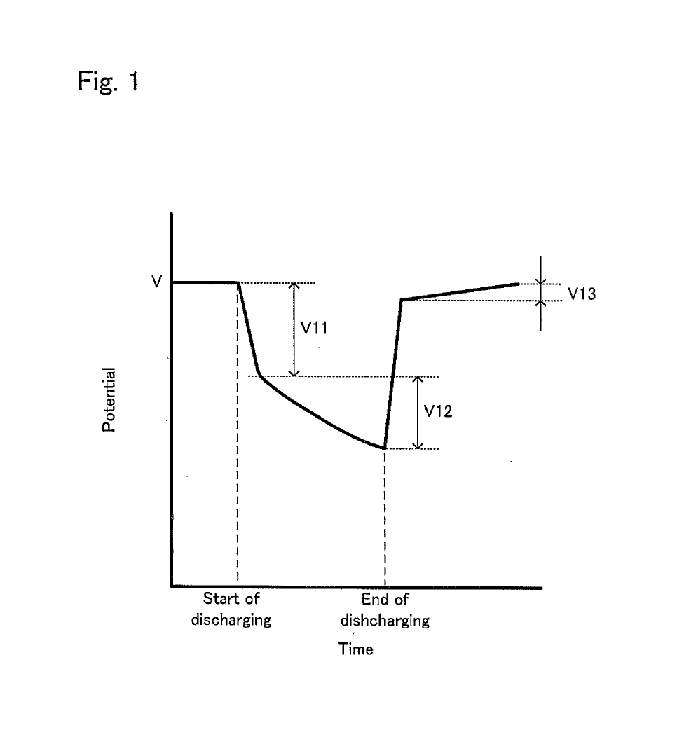

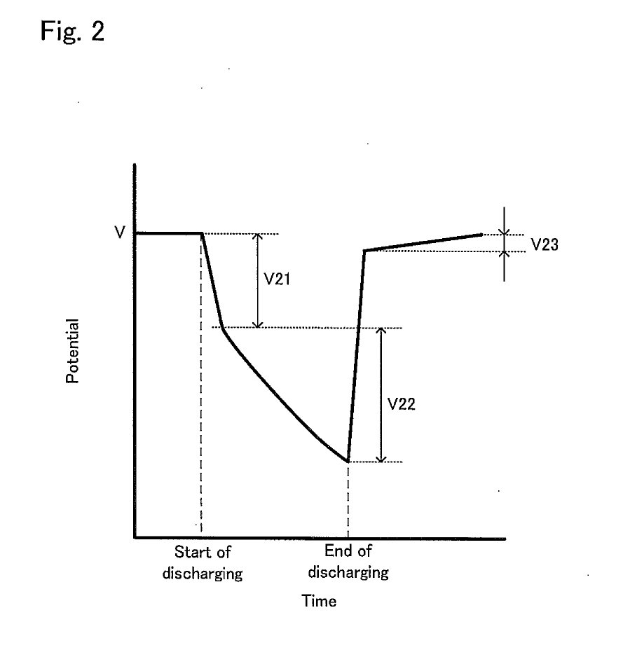

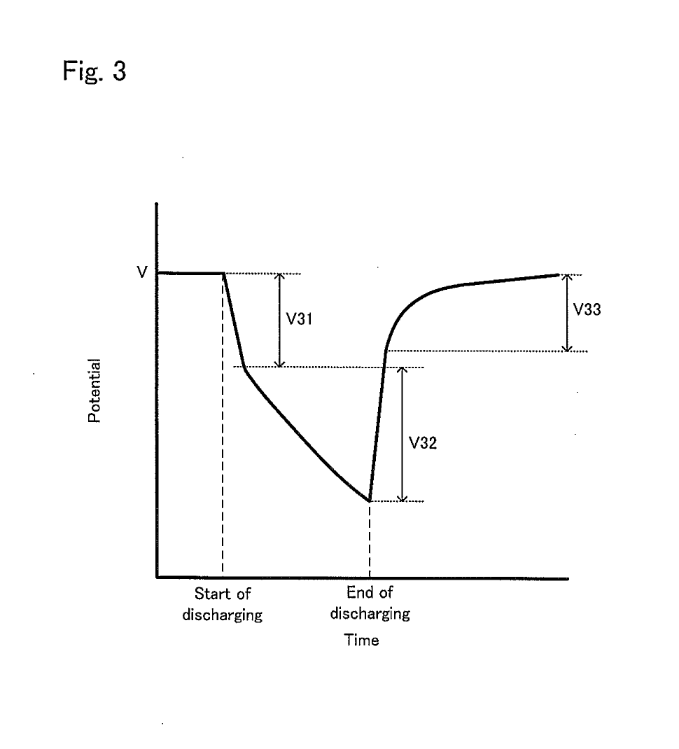

FIG. 1 is a graph to explain the potential variation characteristic of a cell during discharging and after discharging is stopped, the cell being capable of exhibiting the initial performance expected when manufactured with a cathode active material not degraded (hereinafter the cell is sometimes simply referred to as “comparison subject cell”). FIGS. 2 and 3 are graphs to explain the potential variation characteristic of degraded cells during discharging and after discharging is stopped. More specifically, FIG. 2 is a graph to explain the potential variation characteristic of a cell during discharging and after discharging is stopped, the cell in which the cause of degradation does not include degradation of a cathode active material, and FIG. 3 is a graph to explain the potential variation characteristic of a cell during discharging and after discharging is stopped, the cell in which the cause of degradation includes degradation of a cathode active material.

As shown in FIG. 1, when the comparison subject cell is discharged, from the potential V at the start of discharging, the potential drops by only a predetermined amount of V11 immediately after discharging is started in 1 second after discharging is started, preferably in 0.1 second after discharging is started. The same is applied hereinafter). Thereafter, until the discharging is stopped, the potential further drops by only V12. When the discharging is stopped, immediately after that (in 1 second after discharging is stopped, preferably in 0.1 second after discharging is stopped. The same is applied hereafter), the potential rapidly recovers, and thereafter the potential gradually changes to be saturated. When the potential variation amount from the recovery of the potential immediately after discharging is stopped to the saturation of the potential is represented by V13, the potential of the comparison subject cell is recovered by V11+V12−V13, and becomes V−V13 immediately after discharging is stopped.

In contrast, as shown in FIG. 2, when a degraded cell in which an active material is not degraded is discharged from the potential V at the start of discharging with a same state of charge (SOC) and a same current amount as that of the comparison subject cell whose result is shown in FIG. 1, the potential drop amount V21 immediately after discharging is started is almost same as V11, and the potential variation amount V23 from the recovery of the potential immediately after discharging is stopped to the saturation of the potential is almost same as V13. However, the potential drop amount V22 from immediately after the start of charging to the end of discharging becomes larger than V12. The cell whose potential variation characteristic is shown in FIG. 2 has a potential immediately after discharging is stopped of V−V23 (=V−V13).

On the other hand, as shown in FIG. 3, when the cell in which the cause of degradation includes degradation of the active material is discharged from the potential V at the start of discharging, with a same state of charge (SOC) and a same current amount as that of the comparison subject cell whose results are shown in FIG. 1, the potential drop amount V31 immediately after discharging is started is almost same as V11. However, the potential drop amount V32 from immediately after the start of discharging to the end of discharging becomes larger than V12, and the potential variation amount V33 from the recovery of the potential to the saturation of the potential becomes larger than V13. The cell whose potential variation characteristic is shown in FIG. 3 has a potential of V−V33 immediately after discharging is stopped, which is largely different from V−V13.

As describe above, the potential drop amounts (V22, V32) of the degraded cells from immediately after the start of discharging to the end of discharging are larger than that of the comparison subject cell, even if the discharging time of the degraded cells is same as that of the comparison subject cell. Therefore, by examining the potential drop amount from immediately after the start of discharging to the end of discharging, it is possible to diagnose the degree of degradation of the cell. Further, the potential variation characteristic of the cell in which the cathode active material is not degraded immediately after discharging is stopped and the potential variation characteristic of the cell in which the cathode active material is degraded immediately after discharging is stopped are largely different, even though both of the cells are degraded. Therefore, by examining the potentials (V−V23, V−V33) immediately after discharging is stopped, or by examining the magnitude relation of the potential variation amounts (V23, V33) from the recovery to saturation, it is possible to diagnose whether the cathode active material of the cell is degraded or not.

Here, in a case where the potential when discharging is stopped is same as or larger than the minimum potential which is acceptable based on the use form of the cell to which the degradation diagnosis is carried out, it can be considered that the cell to which the degradation diagnosis is carried out is not so degraded as to require a performance recovery treatment (replacement of electrolytic solution, re-pressing and the like that are described later. The same is applied hereinafter). Therefore, the cell can be diagnosed as capable to be continuously used with the same use form as before. In contrast, in a case where the potential when discharging is stopped is smaller than the minimum potential which is acceptable based on the use form of the cell to which the degradation diagnosis is carried out, it is difficult to continuously use the cell at the same use form as before without carrying out the performance recovery treatment. Therefore, in this case, the treatment to recover the performance is carried out to the cell.

Also, in the present invention, in cells that are diagnosed as being degraded since the potential drop amounts (V22, V32) from immediately after the start of discharging to the end of discharging are larger than the potential drop amount (V12) in the comparison subject cell, regarding the cell in which the cathode active material is diagnosed as not being degraded since the potential (V−V23) of the cell immediately after discharging is stopped is same as the potential (V−V13) of the comparison subject cell immediately after discharging is stopped, the cause of degradation can be considered as increase in ion conductivity resistance. Regarding the cell in which the cause of degradation is the increase in ion conductivity resistance, in a case where an electrolytic solution is employed to the cell, by replacing the electrolytic solution, and in a case where a solid electrolyte is employed in the cell, by pressing again the cell and the like, it is possible to reduce the ion conductivity resistance (to recover the performance of the cell). The cell whose performance is recovered as above can be reused. In a case where the cell whose degradation is diagnosed is a cell for vehicle, the cell can be reused as a cell for vehicle if the recovered performance of the cell satisfies the performance criteria required to a cell for vehicle. In contrast, if the recovered performance of the cell does satisfy the performance criteria required for a stationary cell but does not satisfy the performance criteria required for a cell for vehicle, the cell can be reused as a stationary cell.

On the other hand, in cells diagnosed as being degraded, regarding the cell in which the active material is diagnosed as degraded since the potential (VV33) of the cell immediately after discharging is stopped is not same as the potential (V−V13) of the comparison subject cell immediately after discharging is stopped, it is difficult to sufficiently recover the performance of the cell even if the replacement of electrolytic solution or re-pressing is carried out. Regarding the cell in which the active material is diagnosed as degraded, if the performance of a degraded state satisfies the performance required in a form when reused, the cell can be reused as it is. Also, even though the performance in the degraded state does not satisfy the performance required in the form when reused, if the performance recovered by means of replacement of electrolytic solution or re-pressing satisfies the performance required in the form when reused, the cell can be reused after the replacement of electrolytic solution or re-pressing is carried out. In contrast, if the performance recovered by means of replacement of electrolytic solution or re-pressing does not satisfy the performance required in the form when reused, it can be considered that the cell itself needs to be replaced.

In the present invention, the time for carrying out the degradation diagnosis for a cell is not particularly limited. The degradation diagnosis can be carried out when a cell is charged or when the cell is used. Ina case where the degradation diagnosis is carried out when the cell is charged, for example when the cell is charged at night, after adjusting the potential to a prescribed state of charge (SOC), it is possible to obtain the potential variation characteristic by discharging the cell at a prescribed time and current. After obtaining the potential variation characteristic, by comparing it with the potential variation characteristic of the comparison subject cell which is obtained in advance, it is possible to specify the cause of degradation. Also, in a case where the degradation diagnosis is carried out to a cell for vehicle when the cell is used, it is possible to specify the cause of degradation by obtaining the potential variation characteristic in discharging of the cell, for example in acceleration, to compare it with the potential variation characteristic of the comparison subject cell which is obtained in advance.

In the present invention, in view of having a configuration in which the cause of degradation is easy to be specified and the like, the state of charge (SOC) of the cell to which the degradation diagnosis is carried out preferably has a condition as inconvenient for discharging as possible. In a case where the cell is a lithium-ion secondary cell, it is preferred to have a low SOC (for example, a state of charge approximately 20% or less). The discharging rate in discharging the cell to carry out the degradation diagnose is not particularly limited, and preferably the cell is discharged at a discharging rate expected in use of the cell. For example, in a case where the degradation diagnosis is carried out to a cell for vehicle, it is preferable to obtain the potential variation characteristic by discharging the cell for approximately 5 seconds or more and 10 seconds or less at a high rate. In view of having a configuration in which whether the cause of degradation includes degradation of a cathode active material or not is easy to be identified and the like, the potential variation characteristic is preferably obtained by discharging the cell at a high rate.

In the present invention, when the potential variation from the recovery of the potential immediately after discharging is stopped to the saturation of the potential is grasped, sometimes it requires a long time for the potential to be completely saturated. When it can be regarded that there is no potential variation by discharging since the discharging amount is small, it can be regarded that the potential after saturation is equal to the potential before discharging. In this case, the difference between the potential recovered immediately after discharging is stopped and the potential before discharging can be regarded as the potential variation from the recovery immediately after discharging is stopped to the saturation. Also, without waiting the potential to be completely saturated, a potential when a predetermined time (a time at which the potential is judged to be saturated. For example, 1 minute after discharging is stopped) is passed, or a potential when the gradient (derivative value) of the potential at which the potential variation becomes a predetermined value or less (for example, 0.01 or less) can be determined as the saturated potential.

Hereinafter, the reason why whether the active material is degraded or not can be diagnosed by examining the potential variation characteristic after discharging is stopped will be described. An example of a cell having a configuration in which lithium ions transfer between a cathode layer and an anode layer will be taken in the following explanation. However, the cell in which the degradation is diagnosed by the present invention is not limited to the cell in which lithium ions transfer between the cathode layer and the anode layer. The workings described below can be made even in a case where ions other than lithium ions (for example, sodium ions, magnesium ions and the like. The same is applied hereinafter) transfer between a cathode layer and an anode layer. Therefore, the degradation diagnosis of the present invention can be carried out to a cell in which ions other than lithium ions transfer between the cathode layer and the anode layer.

As a result of an intensive study, the inventors of the present invention have considered that, in a case where an all-solid battery is subjected to the degradation diagnosis, the internal reaction can be modeled by the following 4 types. It should be noted that, in the present cell structure, a relationship: electron conductivity resistance<<lithium ion conductivity resistance is satisfied. Therefore, the following study is based on this relationship. Also, it is supposed that a cathode layer of the all-solid cell includes a cathode active material and a solid electrolyte, and an anode active material of the all-solid cell includes an anode active material and a solid electrolyte.

### 1) Occurrence of Electrochemical Reaction Due to Over Voltage

This electrochemical reaction is shown by the Butler-Volmer equation. The Butler-Volmer equation shows that oxidation-reduction current due to electrochemical reaction is occurred more as having a larger over voltage. Here, the term “over voltage” means a difference between an equilibrium potential (standard electrode potential) specific to a material and an actual potential.

### 2) Voltage Drop Caused by Transfers of Electrons and Ions

This voltage drop is shown by Ohm's law. This model explains that the voltage drops depending on the current amount and the resistance of transfer portions when the electrons and lithium ions generated by electrochemical reaction transfer.

3) Diffusion of Lithium Ion from Surface to Inside of Active Material

This diffusion is shown by the Fick's law. This model explains that lithium ions diffuse from a place having a high concentration of lithium to a place having a low concentration of lithium, in order to reduce the difference in concentration of lithium.

### 4) Standard Electrode Potential Variation Relying on Lithium Concentration of Surface of Active Material

This model explains that the standard electrode potential of active material changes depending on Li content. Especially, regarding the standard electrode potential, since the potential at the point of having contact with the material is important, it is needed to focus on the lithium concentration of the surface of active material.

Immediately after discharging is started, an over voltage is applied to the cathode active material and the anode active material, thereby generating an electrochemical reaction to generate current. This phenomenon can be explained by the model 1) described above. Since the over voltage evenly occurs, the electrochemical reaction evenly occurs inside the cathode layer and the anode layer. Electrons and lithium ions generated by the electrochemical reaction transfer inside the cell. The lithium ions transfer along the solid electrolyte, and the electrons transfer in the active material and current collectors (a conductor connected to the cathode layer and a conductor connected to the anode layer. The same is applied hereinafter). At this time, only the lithium ions transfer inside the solid electrolyte layer and only the electrons transfer in the current collectors. However, both of the electrons and the lithium ions transfer inside the cathode layer and the anode layer.

Next, a voltage drop occurs due to the current flowing inside the cathode layer and inside the anode layer. This phenomenon can be explained by the model 2) described above. The lithium ions transfer along the solid electrolyte, and in accordance with this transfer, the potential of the solid electrolyte, which is a reference potential, is dropped. The potential of the active material is also dropped in accordance with the transfer of the electrons. However, the electron conductivity resistance is assumed as small enough, whereby it is possible to consider that the potential gradient is not created here.

In the following step (the early stage of discharging) after the above reaction is occurred, a lot of lithium ions exist on a solid electrode layer side of the cathode layer and on a solid electrode layer side of the anode layer. Therefore, different reference potentials (the potential of the solid electrolyte) are created between on a side close to the solid electrolyte layer and on a side far from the solid electrolyte solid layer, in the cathode layer and the anode layer. That is, the reference potential inclines and in accordance with this, the standard electrode potential of the active material also inclines. Therefore, a distribution of the over voltage is occurred in the cathode layer and the anode layer. In a case where the lithium ion conductivity resistance is sufficiently large compared to the electron conductivity resistance, the over voltage becomes large on the solid electrolyte layer side, and the electrochemical reaction increases on the solid electrolyte layer side. This phenomenon can be explained by the model 1) described above. That is, the reaction of the all-solid cell at early stage of discharging is partially occurs on the solid electrolyte side due to deviation of the over voltage.

In order for the lithium ions and the electrons to transfer to the reaction part on the solid electrolyte layer side, the electrons need to transfer the distance between the current collector to the neighborhood of the solid electrolyte, whereas the lithium ions only need to transfer a short distance from the solid electrolyte layer. Therefore, mainly the electrons transfer inside the cathode layer and the anode layer, and the lithium ions hardly transfer inside the cathode layer or the anode layer at the early stage of discharging. It can be considered that the internal resistance of the cell at the early stage of discharging includes the electron conductivity resistance inside the cathode layer and the anode layer, the lithium ion conductivity resistance inside the solid electrolyte layer, the electron conductivity resistance of the current collector, and the resistance of the electrochemical reaction.

When the lithium concentration of the surface of the active material on the solid electrolyte side is changed (the surface of the cathode active material changes so that the concentration increases and the surface of the anode active material changes so that the concentration decreases) with the reaction progressing, the surface potential of the active material itself is changed, then the surface potential of the cathode active material is decreased and the surface potential of the anode active material is increased. This phenomenon can be explained by the model 4) described above. This reduces the deviation of the over voltage in a thickness direction of the cathode layer and the anode layer, which enables the electrochemical reaction used to occur a lot on the solid electrolyte side to occur on a current collector side (on a side far from the solid electrolyte layer) as well. As a result, the lithium ions start to transfer inside the cathode layer and the anode layer. Here, since the lithium ion conductivity resistance inside the cathode layer and inside the anode layer is extremely large compared to the electron conductivity resistance, the resistance of whole cell is also increased. This is presumed as the workings of increase in the internal resistance of an all-solid battery as time passes.

Since the reaction occurs a lot on the solid electrolyte layer side immediately after discharging is started, the electrons transfer inside the cathode layer and the anode layer. However, as time passes, the reaction starts to occur on the current collector side as well, whereby the lithium ion also starts to transfer inside the cathode layer and the anode layer. Since the lithium ion conductivity resistance is larger than the electron conductivity resistance, when the lithium ion starts to transfer as time passes, the potential largely drops. In addition, the equilibrium potential of the active material itself also changes in accordance with the discharging. These can be considered as the reason why potential drop is observed as time passes since immediately after discharging is started.

As described above, the potential variation during discharging includes the variation caused by the transfer of electrons and lithium ions and the variation caused by the equilibrium potential variation of the active material. However, if the discharging is stopped, the electrons and the lithium ions stop transferring. Therefore only the equilibrium potential variation is remained. The lithium ion concentration at the surface of the active material differs in each portion. Therefore, even though the discharging is stopped, the lithium concentration of the surface of the active material does not become even immediately. Thus, the surface potential variation of the active material is remained even the discharging is stopped. This phenomenon can be explained by the models 3) and 4) described above. The potential variation caused by the surface potential variation of the active material is observed as the potential variation from the recovery of the potential immediately after discharging is stopped to the saturation of the potential. That is, by observing the potential immediately after discharging is stopped and the potential variation from the recovery of the potential immediately after discharging is stopped to the saturation of the potential, it is possible to grasp how easy the lithium ions are absorbed to the cathode active material (degree of the degradation of the cathode active material).

The configuration of the cell in which the cause of degradation is diagnosed by the present invention is not particularly limited as long as the cell is a secondary cell. The cell may have a configuration in which an electrolytic solution is employed, or may be an all-solid cell employing a solid electrolyte. In a case where the cell in which the cause of degradation is diagnosed by the present invention is a lithium-ion secondary cell, a cathode active material which can be used for a lithium-ion secondary battery can be adequately employed for the cathode active material to be contained in the cathode layer. Examples of the cathode active material include layer type active materials such as lithium cobalt oxide (LiCoO₂) and lithium nickel oxide (LiNiO₂), olivine type active materials such as olivine type iron lithium phosphate (LiFePO₄), and spinel type active materials such as spinel type lithium manganate (LiMnO₄) and the like. The cathode active material may be formed in a particle shape, a thin film shape and the like for example. The average particle diameter (D50) of the cathode active material is, for example preferably 1 nm or more and 100 μm or less, and more preferably 10 nm or more and 30 μm or less.

In a case where the cell in which the cause of degradation is diagnosed by the present invention is an all-solid battery, the all-solid battery can contain a known solid electrolyte which can be used for an all-solid battery, not only in the solid electrolyte layer, but also in the cathode layer and the anode layer. Examples of the solid electrolyte includes oxide-based amorphous solid electrolytes such as Li₂O—B₂O₃—P₂O₅ and Li₂O—SiO₂, sulfide-based amorphous solid electrolytes such as Li₂S—SiS₂, LiI—Li₂S—P₂S₅, LiI—Li₂S—P₂O₅, LiI—Li₃PO₄—P₂S₅, Li₂S—P₂S₅, and Li₃PS₄, crystalline oxides or crystalline oxynitrides such as LiI, Li₃N, Li₅La₃Ta₂O₁₂, Li₇La₃Zr₂O₁₂, Li₆BaLa₂Ta₂O₁₂, Li₃PO_{(4-3/2w)}N_{w} (w<1), and Li_{3.6}Si_{0.6}P_{0.4}O₄. In view of having a configuration in which the performance of the all-solid battery can be easily improved and the like, it is preferable to use a sulfide solid electrolyte for the solid electrolyte.

In a case where a sulfide solid electrolyte is used for the solid electrolyte, in view of having a configuration in which the cell resistance is easy to be prevented from being increased, by making it difficult to form a high resistance layer on the interface between the cathode active material and the solid electrolyte, it is preferable that the cathode active material is covered with an ion-conductive oxide. Examples of lithium ion conductive oxide to cover the cathode active material include oxides represented by the general formula LiₓAO_{y} (A is B, C, Al, Si, P, S, Ti, Zr, Nb, Mo, Ta, or W; x and y are positive numbers). Specifically, Li₃BO₃, LiBO₂, Li₂CO₃, LiAlO₂, Li₄SiO₄, Li₂SiO₃, Li₃PO₄, Li₂SO₄, Li₂TiO₃, Li₄Ti₅O₁₂, Li₂Ti₂O₅, Li₂ZrO₃, LiNbO₃, Li₂MoO₄, Li₂WO₄ and the like can be exemplified. The lithium ion conductive oxide may be a composite oxide. As the composite oxide to cover the cathode active material, the above lithium ion conductive oxides can be arbitrary combined. For example, Li₄SiO₄—Li₃BO₃, Li₄SiO₄—Li₃PO₄ and the like may be given. Ina case where the surface of the cathode active material is covered with the ion conductive oxide, it is only necessary that the ion conductive oxide cover at least one part of the cathode active material, and it may cover the whole surface of the cathode active material. The thickness of the ion conductive oxide to cover the cathode active material is preferably 0.1 nm or more and 100 nm or less for example, and more preferably 1 nm or more and 20 nm or less. The thickness of the ion conductive oxide can be measured by means of a transmission type electron microscope (TEM) for example.

When the cell in which the cause of degradation is diagnosed by the present invention is an all-solid cell, the cathode layer of the all-solid cell may be produced by a known binder which can be contained in the cathode layer of a lithium-ion secondary cell. Examples of the binder include acrylonitrile butadiene rubber (NBR), butadiene rubber (BR), polyvinylidene fluoride (PVdF), styrene-butadiene rubber (SER) and the like.

Further, the cathode layer may contain a conductive material which can improve conductivity. Examples of the conductive material which can be contained in the cathode layer include carbon materials such as vapor-phase growth carbon fiber, acetylene black (AB), Ketjen black (KB), carbon nanotube (CNT), carbon nanofiber (CNF), and metal materials that can endure the environment in use of a solid cell. In a case where the cathode layer is produced with a cathode composition in a slurry form adjusted by dispersing the above cathode active material, the solid electrolyte, the binder and the like in a liquid, heptanes and the like can be exemplified as the liquid which can be used, and a nanopolar solvent is preferably used. The thickness of the cathode layer is, for example preferably 0.1 μm or more and 1 mm or less, and more preferably 1 μm or more and 100 μm or less. In a case where the cell in which the cause of degradation is diagnosed is an all-solid cell, in order to make the performance of the all-solid cell easy to be improved, the cathode layer is preferably produced by going through a process of pressing. In the present invention, the pressure to press the cathode layer may be approximately 100 MPa.

In a case where the cell in which the cause of degradation is diagnosed by the present invention is a lithium-ion secondary cell, as the anode active material to be contained in the anode layer, a known anode active material which can store/release lithium ions may be adequately used. Examples of the anode active material include carbon active materials, oxide active materials, metal active materials and the like. The carbon active materials are not particularly limited as long as they contain carbon. Mesocarbon microbeads (MOMS), highly oriented graphite (HOPG), hard carbons, soft carbons and the like may be exemplified. Examples of the oxide active materials include Nb₂O₅, Li₄Ti₅O₁₂, SiO and the like. Examples of the metal active materials include In, Al, Si, Sn and the like. Also, a lithium-containing metal active material may be used for the anode active material. The lithium-containing metal active material is not particularly limited as long as it is an active material containing at least Li. The lithium-containing metal active material may be an Li metal or may be an Li alloy. Examples of the Li alloy include an alloy containing Li and at least one kind selected from In, Al, Si, and Sn. The anode active material can be formed in a particle shape, a thin film shape and the like for example. The average particle diameter (D50) of the anode active material is for example preferably 1 nm or more and 100 μm or less, and more preferably 10 nm or more and 30 μm or less.

Further, the anode layer can contain a solid electrolyte, and it also can contain a binder which binds the anode active material and the solid electrolyte, and a conductive material which improves conductivity. As the binder and the conductive material that can be contained in the anode layer, the above binders and conductive materials that can be contained in the cathode layer may be exemplified. In a case where the anode layer is produced with an anode composition in a slurry form adjusted by dispersing the above anode active material and the like in a liquid, as the liquid to disperse the anode active material and the like, heptanes and the like may be exemplified, and a nonpolar solvent may be preferably used. Also, in a case where the cell in which the cause of degradation is diagnosed by the present invention is an all-solid cell, in order to make it easy to improve the performance of the all-solid cell, the anode layer is preferably produced by going through a process of pressing. In the present invention, the pressure to press the anode layer is preferably 200 MPa or more, and more preferably approximately 400 MPa.

Also, in a case where the cell in which the cause of degradation is diagnosed by the present invention is a lithium-ion secondary cell which is an all-solid cell using a solid electrolyte layer, as the solid electrolyte to be contained in the solid electrolyte layer, a known solid electrolyte which can be used for the all-solid cell may be adequately used. As the solid electrolyte, the above solid electrolytes and the like that can be contained in the cathode layer and the anode layer may be exemplified. In addition, the solid electrolyte layer may contain a binder for binding the solid electrolyte, in view of having plasticity and the like. As the binder, the above binders that can be contained in the cathode layer may be exemplified. However, in view of enabling a formation of a solid electrolyte layer in which the solid electrolyte is evenly dispersed and preventing excessive aggregation of the solid electrolyte, in order to make it easy to realize the high output, the content of the binder to be contained in the solid electrolyte layer is preferable 5% by mass or less. Also, in a case where the solid electrolyte layer is produced by a process of applying the solid electrolyte composition to the cathode layer and the anode layer, the composition being in a slurry form adjusted by dispersing the above solid electrolyte in a liquid, as the liquid to disperse the solid electrolyte and the like, heptanes can be exemplified, and a nonpolar solvent may be preferably used. The content of the solid electrolyte material in the solid electrolyte layer is, by mass %, for example preferably 60% or more, more preferably 70% or more, and especially preferably 80% or more. The thickness of the solid electrolyte layer is, depending on the structure of the cell, for example preferably 0.1 μm or more and 1 mm or less, and more preferably 1 μm or more and 100 μm or less.

For the current collectors to be connected to the cathode layer and the anode layer, a known metal which can be used for a current collector of a lithium-ion secondary cell can be used. As the metal, a metal material including one or two or more element(s) selected from the group consisting of Cu, Ni, Al, V, Au, Pt, Mg, Fe, Ti, Co, Cr, Zn, Ge, and In may be exemplified.

The cell in which the cause of degradation is diagnosed by the present invention may be used in a state being wrapped by a housing such as a laminate film. Examples of the laminate film include a laminate film made of resin, a film in which a metal is evaporated to a laminate film made of resin.

In addition, in a case where the cell in which the cause of degradation is diagnosed by the present invention is a lithium-ion secondary cell which employs an electrolytic solution, for the electrolytic solution, a known electrolytic solution which can be used for a lithium-ion secondary cell may be adequately used.

In the above explanation regarding the present invention, a configuration in which the cause of degradation is specified by comparing the potential variation characteristic of the comparison subject cell during discharging and after discharging is stopped and the potential variation characteristic of the degradation diagnosis subject cell during discharging and after discharging is stopped is mainly explained. However, the present invention is not limited to this configuration. The present invention may have a configuration in which whether the cause of degradation includes degradation of an active material or not is diagnosed by means of examining a potential of the degradation diagnosis cell immediately after discharging is stopped (or a potential variation speed of the degradation diagnosis cell immediately after discharging is stopped) without using the comparison subject cell.

Also, in the above explanation regarding the present invention, a configuration in which the cell in which the cause of degradation is diagnosed by the present invention is a lithium-ion secondary cell is exemplified. However, the present invention is not limited to this configuration. The cell in which the cause of degradation is diagnosed by the present invention may be a secondary cell having a configuration in which ions other than lithium ions transfer between a cathode layer and an anode layer. Examples of the ions include sodium ions, magnesium ions and the like. In a case where ions other than lithium ions transfer, the cathode active material, the solid electrolyte, and the anode active material may be adequately chosen depending on the ions to transfer.

### EXAMPLES

### 1. Degradation Diagnosis

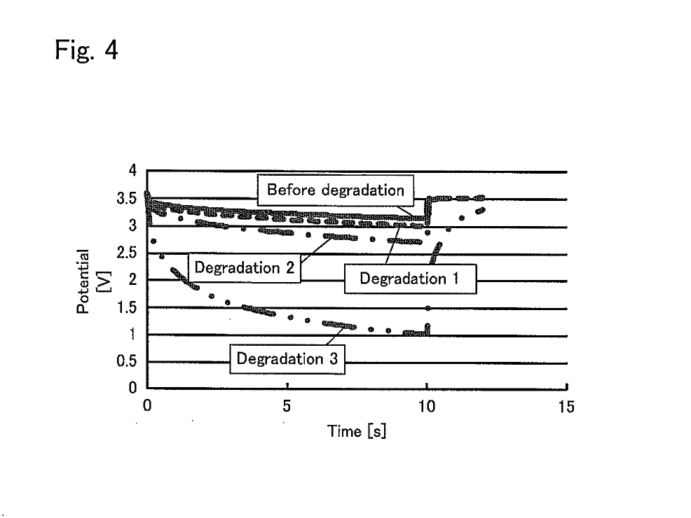

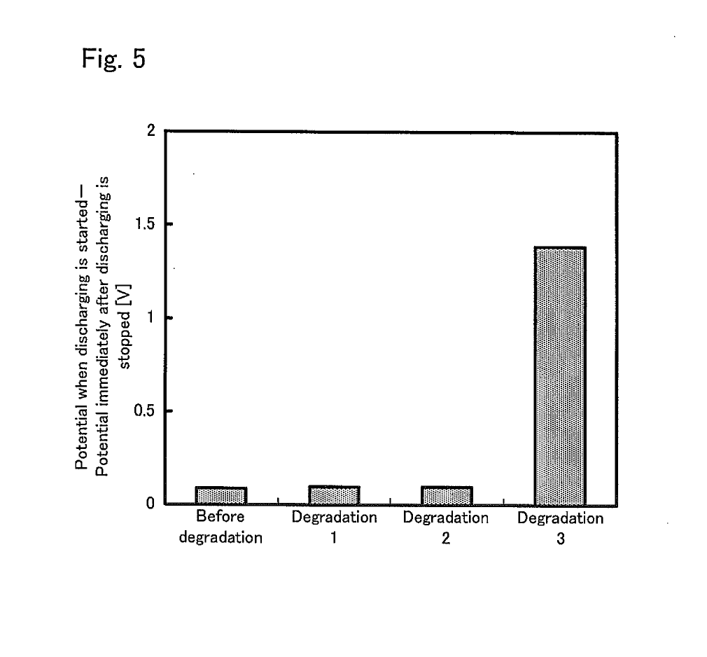

Four sample cells each having a state of before degradation or of after degradation were discharged at a discharging rate of 3 C, from a voltage of 3.6V when discharging is started. Results are shown in FIG. 4. Here, among the 4 samples, only one sample was an all-solid cell which can exhibit the initial performance expected when manufactured, and other 3 samples were degraded all-solid cells. In FIG. 4 and FIG. 5 which is described later, the results of the cell which can exhibit the initial performance expected when manufactured were shown as “before degradation”, and the results of the degraded cells were shown as “degradation 1”, “degradation 2”, and “degradation 3”.

As shown in FIG. 4, the degradation 1 and the degradation 2 had similar potentials immediately after discharging was stopped (the potentials 0.1 second after discharging was stopped. The same is applied hereinafter) to the potential of the cell of before degradation immediately after discharging was stopped. However, the potential of the cell of degradation 3 immediately after discharging was stopped was largely different from the other three samples.

FIG. 5 shows differences of the potential when discharging is started and the potential immediately after discharging is stopped. As shown in FIG. 5, the cell of before degradation, and the cells of degradation 1 and degradation 2 each had a difference between the potential when discharging was started and the potential immediately after discharging was stopped of less than 0.1 V. However, the cell of degradation 3 had a difference between the potential when discharging was started and the potential immediately after discharging was stopped of approximately 1.4 V. From the results shown in FIGS. 4 and 5, the cause of degradation of the cells of which results are shown by degradation 1 and degradation 2 was diagnosed as being other than an active material, and the cause of degradation of the cell of which results are shown by degradation 3 was diagnosed as including degradation of an active material.

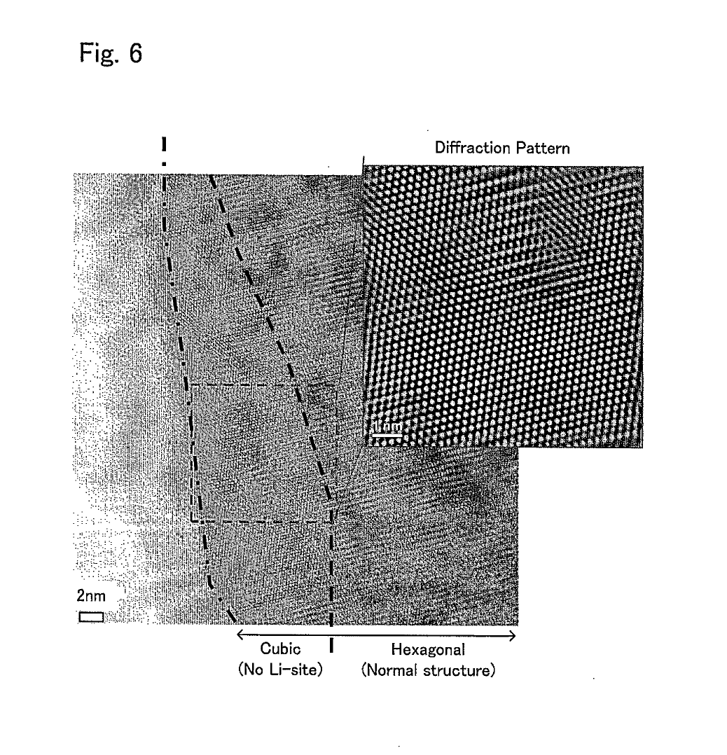

The cathode active material of the cell of which results are shown by degradation 3 was observed by means of a transmission type electron microscope (JSM6610LA, manufactured by JEOL Ltd.). Results are shown in FIG. 6. As shown in FIG. 6, in the cathode active material of the cell of degradation 3, a portion of the surface was observed in which the crystal structure has been changed from the normal structure of hexagonal crystal having an empty space where lithium can be stored to cubical crystal which does not have any space where lithium can be stored. As described above, it was shown that, in the cell in which the cause of degradation was diagnosed as including degradation of the active material, a structure of a part of the active material is changed so that lithium cannot be stored. Therefore, the portion where reactions occur is reduced, and the reactions concentrated to the portion where the crystal structure has not been changed. As a result, the potential variation on the surface of the active material was increased.

### 2. Effect Confirmation Test for Performance Recovery Treatment

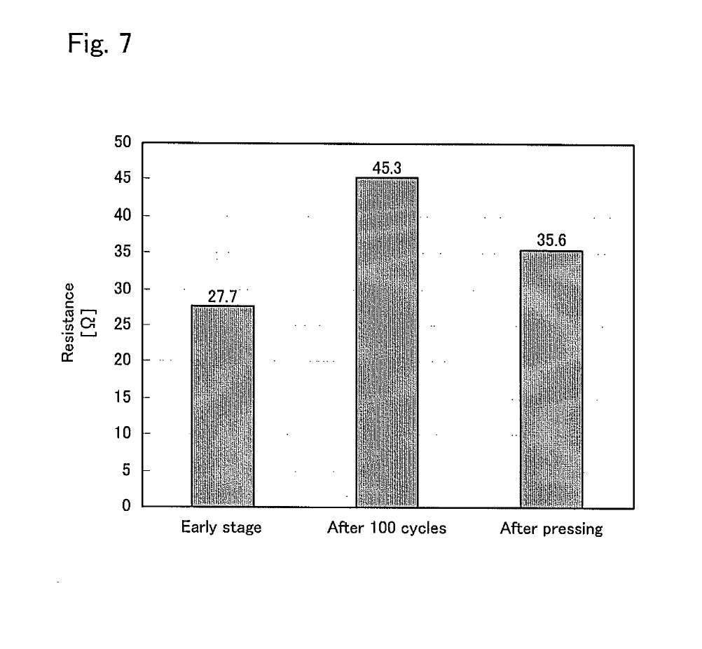

The degree of performance recovery was examined when the performance recovery treatment was carried out to the cell in which the cause of degradation is diagnosed as being other than the active material. For an all-solid cell provided with a cathode layer which employs LiNi_{1/3}CO_{1/3}Mn_{1/3}O₂ for a cathode active material and an anode layer which employs graphite for an anode active material, resistances at the early stage of charging and discharging, after 100 cycles of charging and discharging at 10 rate at 60° C., and after pressing was carried out with a pressure of 800 MPa were measured. Results are shown in FIG. 7.

As shown in FIG. 7, the resistance of a full cell and a half cell increased by approximately 20Ω by the 100 cycles of charging and discharging. However, by carrying out pressing after 100 cycles of charging and discharging, it was possible to decrease the resistance by approximately 10Ω. As described above, it was shown that an all-solid cell diagnosed as being degraded recovers the performance by pressing again the cell.

1-7. (canceled)

8. A degradation diagnosis device for a cell, the device comprising:
a memory unit for storing a potential variation characteristic of a comparison subject cell during discharging and after discharging is stopped; and
a specifying unit for comparing a potential variation characteristic of a degradation diagnosis subject cell during discharging and after discharging is stopped and the potential variation characteristic of the comparison subject cell during discharging and after discharging is stopped stored in the memory unit to specify a cause of degradation of the degradation diagnosis subject cell based on a difference between the potential variation characteristic of the degradation diagnosis subject cell during discharging and after discharging is stopped and the potential variation characteristic of the comparison subject cell during discharging and after discharging is stopped,
wherein
in the specifying unit, in a case where a potential of the degradation diagnosis subject cell immediately after discharging is stopped is not same as a potential of the comparison subject cell immediately after discharging is stopped, the cause of degradation is diagnosed as including degradation of an active material, and in a case where the potential of the degradation diagnosis subject cell immediately after discharging is stopped is same as the potential of the comparison subject cell immediately after discharging is stopped, the cause of degradation is diagnosed as being other than the active material.

9. A degradation diagnosis device for a cell, the device comprising a specifying unit for specifying a cause of degradation of a degradation diagnosis subject cell by means of at least a potential variation characteristic of the degradation diagnosis subject cell after discharging is stopped,
wherein
in the specifying unit, in a case where a potential of the degradation diagnosis subject cell immediately after discharging is stopped is smaller than a predetermined potential, a cause of degradation is diagnosed as including degradation of an active material, and in a case where the potential of the degradation diagnosis subject cell immediately after discharging is stopped is same as or larger than the predetermined potential, the cause of degradation is diagnosed as being other than the active material.

10. The degradation diagnosis device for a cell according to claim 8,
wherein
during the degradation diagnosis subject cell is discharged, in a case where the potential does not drop to a minimum potential which is acceptable based on a use form of the degradation diagnosis subject cell, the degradation diagnosis subject cell is diagnosed as capable of being continuously used.

11. The degradation diagnosis device for a cell according to claim 9,
wherein
during the degradation diagnosis subject cell is discharged, in a case where the potential does not drop to a minimum potential which is acceptable based on a use form of the degradation diagnosis subject cell, the degradation diagnosis subject cell is diagnosed as capable of being continuously used.

12. A degradation diagnosis method for a cell, the method comprising:
a pre-degradation characteristic grasping step of grasping a potential variation characteristic of a comparison subject cell during discharging and after discharging is stopped;
a characteristic obtaining step of obtaining a potential variation characteristic of a degradation diagnosis subject cell during discharging and after discharging is stopped; and
a degradation cause specifying step of comparing the potential variation characteristic obtained in the pre-degradation characteristic grasping step and the potential variation characteristic obtained in the characteristic obtaining step to specify a cause of degradation of the degradation diagnosis subject cell based on a difference between the potential variation characteristic obtained in the pre-degradation characteristic grasping step and the potential variation characteristic obtained in the characteristic obtaining step,
wherein
the degradation cause specifying step comprises:
in a case where a potential of the degradation diagnosis subject cell immediately after discharging is stopped which is obtained in the characteristic obtaining step is not same as a potential of the comparison subject cell immediately after discharging is stopped which is obtained in the pre-degradation characteristic grasping step, diagnosing the cause of degradation as including degradation of an active material; and
in a case where the potential of the degradation diagnosis subject cell immediately after discharging is stopped which is obtained in the characteristic obtaining step is same as the potential of the comparison subject cell immediately after discharging is stopped which is obtained in the pre-degradation characteristic grasping step, diagnosing the cause of degradation as being other than the active material.

13. A degradation diagnosis method for a cell, the method comprising:
a characteristic obtaining step of obtaining at least a potential variation characteristic of a degradation diagnosis subject cell after discharging is stopped; and
a degradation cause specifying step of specifying a cause of degradation of the degradation diagnosis subject cell by means of the potential variation characteristic obtained in the characteristic obtaining step,
wherein
the degradation cause specifying step comprises;
in a case where a potential of the degradation diagnosis subject cell immediately after discharging is stopped is smaller than a predetermined potential, diagnosing the cause of degradation as including degradation of an active material; and
in a case where the potential of the degradation diagnosis subject cell immediately after discharging is stopped is same as or larger than the predetermined potential, diagnosing the cause of degradation as being other than the active material.

14. The degradation diagnosis method for a cell according to claim 12, the method comprising diagnosing the degradation diagnosis subject cell as capable of being continuously used, in a case where the potential does not drop to a minimum potential which is acceptable based on a use form of the degradation diagnosis subject cell during the degradation diagnosis subject cell is discharged.

15. The degradation diagnosis method for a cell according to claim 13, the method comprising diagnosing the degradation diagnosis subject cell as capable of being continuously used, in a case where the potential does not drop to a minimum potential which is acceptable based on a use form of the degradation diagnosis subject cell during the degradation diagnosis subject cell is discharged.

16. A method for manufacturing a cell, the method comprising:
a cell producing step;
a degradation diagnosis step of carrying out a degradation diagnosis to a cell produced in the cell producing step, by means of the degradation diagnosis method for a cell according to claim 12; and
a diagnosis result reflection step comprising:
if the cell is diagnosed in the degradation diagnosis step that a cause of degradation includes degradation of an active material, replacing the cell by a single cell unit; and
if the cell is diagnosed in the degradation diagnosis step that the cause of degradation is other than the active material, replacing an electrolyte of the cell or pressing the cell.

17. A method for manufacturing a cell, the method comprising:
a cell producing step;
a degradation diagnosis step of carrying out a degradation diagnosis to a cell produced in the cell producing step, by means of the degradation diagnosis method for a cell according to claim 13; and
a diagnosis result reflection step comprising:
if the cell is diagnosed in the degradation diagnosis step that a cause of degradation includes degradation of an active material, replacing the cell by a single cell unit; and
if the cell is diagnosed in the degradation diagnosis step that the cause of degradation is other than the active material, replacing an electrolyte of the cell or pressing the cell.

18. The method for manufacturing a cell according to claim 16,
wherein
the degradation diagnosis step comprises diagnosing the degradation diagnosis subject cell as capable of being continuously used, in a case where the potential does not drop to a minimum potential which is acceptable based on a use form of the degradation diagnosis subject cell during the degradation diagnosis subject cell is discharged.

19. The method for manufacturing a cell according to claim 17,
wherein
the degradation diagnosis step comprises diagnosing the degradation diagnosis subject cell as capable of being continuously used, in a case where the potential does not drop to a minimum potential which is acceptable based on a use form of the degradation diagnosis subject cell during the degradation diagnosis subject cell is discharged.
